(19) United States
(12) Patent Application Publication
(10) Pub. No.: US 2008/0062866 A1
(43) Pub. Date: Mar. 13, 2008

(54) Methods which avoid cluster in a wireless mesh network and systems and devices thereof

(75) Inventors: Chungjun Jiang, Aliso Viejo, CA (US); Hong Helena Zheng, Aliso Viejo, CA (US); Jack Han-Chin Tai, San Gabriel, CA (US); Hui Lu, Beijing (CN)

Correspondence Address: Jenny Chen, 7F, No. 1, Alley 30, Lane 358,, Rueiguang Road, Neihu District, Taipei, 114, omitted

(73) Assignee: 3DSP Corporation

(21) Appl. No.: 11/900,159

(22) Filed: Sep. 11, 2007

Related U.S. Application Data
(60) Provisional application No. 60/843,298, filed on Sep. 11, 2006.

(51) Int. Cl. G01R 31/08; H04L 12/28; H04Q 7/24

(52) U.S. Cl. 370/229; 370/238; 370/338; 370/400; 709/239

(57) ABSTRACT

The present invention discloses methods, systems and devices which avoid a cluster in a wireless network. The method of the present invention may include locating a node with a direct or indirect connection to a destination.

### CROSS-REFERENCE TO RELATED APPLICATIONS

This application is related to and claims priority to U.S. provisional patent application, U.S. Provisional Application No. 60/843,298, filed on Sep. 11, 2006, by the applicants Chongjun Jiang et al., entitled “Methods to Avoid Cluster In A Wireless Mesh Network And The System Thereof”.

### FIELD OF THE INVENTION

The present invention relates to methods, systems and devices which avoid a cluster in a wireless mesh network. Particularly, the present invention relates to methods, systems and devices which avoid a cluster in a wireless mesh network technology utilizing network connection indicators.

### BACKGROUND OF THE INVENTION

In a conventional wireless mesh network technology such as those shown in FIGS. 1A, 1B and 1C, nodes are utilized to pass and receive information. A node within a wireless mesh network can be either an originator or a destination for information flow. Each wireless node acts as a relay point for its peers for information transfer. A peer node is only good to a node if that peer node can reliably transmit and receive packets to and from the node. And to pass information, a node passes such information to one of its peer nodes, which then passes the information to one of the peer nodes' peer nodes, and so on and so forth, until the information reaches its destination. Thus, as in FIG. 1A, when peer node 51 desires to pass information to destination 50, peer node 51 may pass the information first to peer node 53. Peer node 53 then passes the information to destination 50. And a node receives information in a similar manner. In order to ensure the transfer and receipt of information, each node maintains a list of reliable peer nodes for information transfer.

Typically, a probe packet is used to locate the peer nodes in the wireless mesh network and establish a peer list. To economically and efficiently maintain the peer list, typically, only a finite number of peers is maintained in the list. For example, as illustrated in FIG. 1C, one may designate that a node must have at least three peer nodes in its peer list to form a four-node peer-to-peer network. With such a designation, when a node finds three reliable peer nodes, the probe packet for that node may stop looking for additional peer nodes. On the other hand, when a probe packet cannot locate the finite number of peer nodes, the probe packet will increase its power until sufficient number of peer nodes is found. Once sufficient number of peer nodes in the wireless mesh network is found, routing tables are then built on top of the peer list to reach any destination within the network.

The routing table may contain routing entries for the node, identifying through which peer node or nodes to reach a certain destination. The routing table may contain routing entries not only for the node itself, but also for its peers. Typically, each wireless node broadcasts its routing table to the peers through additional probe packets such that routing information may be obtained or requested through those probe packets. Thus, for example, in FIG. 1A, when peer node 51 desires to pass information to destination 60, peer node 51 may pass the information first to peer node 52, which then passes the information to peer node 63. Peer node 63 then passes the information to destination 60. Alternatively, peer node 51 may pass information first to peer node 52, which then passes the information to peer node 61, which then passes to peer node 62. Peer node 62 then passes the information to peer node 63 which then passes the information to destination 60.

However, for any wireless peer-to-peer network to provide a reliable connection to a destination, such as the Internet, it relies on evenly distributed nodes to provide relay to such destination, such as a gateway. If a group of nodes forms a closed cluster, such as peer-to-peer network 30c in FIG. 1B, the nodes within the cluster may think they have enough peers to reach any destination and are thus well connected. Consequently, this group of nodes will not attempt to reach out to nodes outside the cluster. If none of the nodes within the cluster has connection to a destination in the network, such as the destination 50c, then the whole cluster 30c will lose the connection.

In such a case, the nodes can only talk to each other within the cluster, but they can't talk to any nodes outside the cluster. Additionally, none of the nodes is aware of the problem, since each of them think it is well connected with sufficient number of neighbors. No attempt will be made to change the situation.

The same problem also exists when a wireless peer-to-peer network technology is applied to applications other than an Internet connection. When a group of wireless mesh nodes tries to form a network coverage for an area, allowing any one node in the group to communicate with any other node in the group, the above cluster problem may also exist. If a subset of the nodes within the group forms a cluster, then any node inside the cluster will not be able to talk to any node outside the cluster. The network is thus broken.

The problem may be resolved by designating a larger number of peers in the peer list, thus increasing the chance of a connection to all destinations and minimizing the occurrence of cluster. However, this solution unnecessarily burdens the peer list and wastes power and resources of the probe packet. There is also no telling when a peer number is sufficiently large. For example, in a crowded network, where a node may have many neighboring nodes, the node may need to have quite an extensive list of peer nodes in its peer list in order to overcome the cluster problem.

Therefore, there is a need for a method, system and electronic device capable of avoiding a cluster in a wireless mesh network.

### SUMMARY OF THE INVENTION

One object of the present invention is to provide a method to avoid a cluster in a wireless mesh network. The method of the present invention may comprise a step of locating a node with a direct or indirect connection to a destination connected to the network.

Another object of the present invention is to provide a method to avoid a cluster in a wireless mesh network. The method of the present invention may comprise a step of broadcasting in the network when a direct or indirect connection to a destination connected to the network exists.

Yet another object of the present invention is to provide a wireless mesh network. The wireless mesh network of the present invention may comprise a node with a direct or indirect connection to a destination connected to the network, wherein the node broadcasts in the network its direct or indirect connection to the destination.

Yet another object of the present invention is to provide a wireless mesh network. The wireless mesh network of the present invention may comprise a node, wherein the node locates or attempts to locate a direct or indirect connection to a destination connected to the network.

Yet another object of the present invention is to provide an electronic device in a wireless network. The electronic device of the present invention may comprise a hardware or software capable of connecting to the network, wherein the device locates or attempts to locate an indirect connection to a destination.

Yet another object of the present invention is to provide an electronic device in a wireless mesh network. The electronic device of the present invention may comprise a hardware or software capable of connecting to the network, wherein the device directly or indirectly connects to a destination within the network and broadcasts to the network the direct or indirect connection.

Other objects of the present invention can be readily ascertained by one of ordinary skilled in the arts upon review of the detailed descriptions of the preferred embodiments.

### BRIEF DESCRIPTION OF THE DRAWINGS

FIGS. 1A, 1B and 1C are schematic views of wireless mesh networks; and

FIG. 2 illustrates a flow chart of a method to avoid a cluster in a wireless mesh network in accordance with the present invention.

### DETAILED DESCRIPTION OF THE EMBODIMENTS

In accordance with the present invention, each node in a wireless mesh network may be aware of its connection status or connection ability to a destination within the network. This can be done through a signal indicator such as a connection status indicator (CSI). For illustrative purposes, an Internet application is used as an application of the present invention. However, those skilled in the art should know that such signal indicator or other indicating or signaling means such as flags may also be used in other applications to allow each node in a network to be aware of its connection status or connection ability to the rest of the nodes within the network.

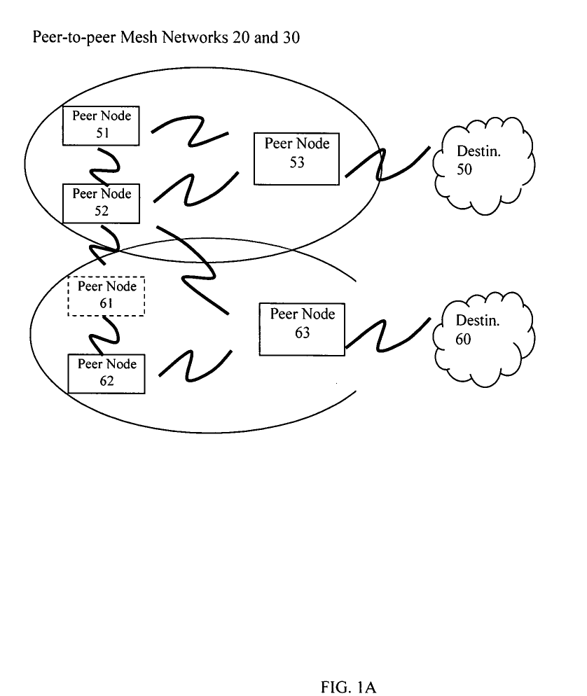

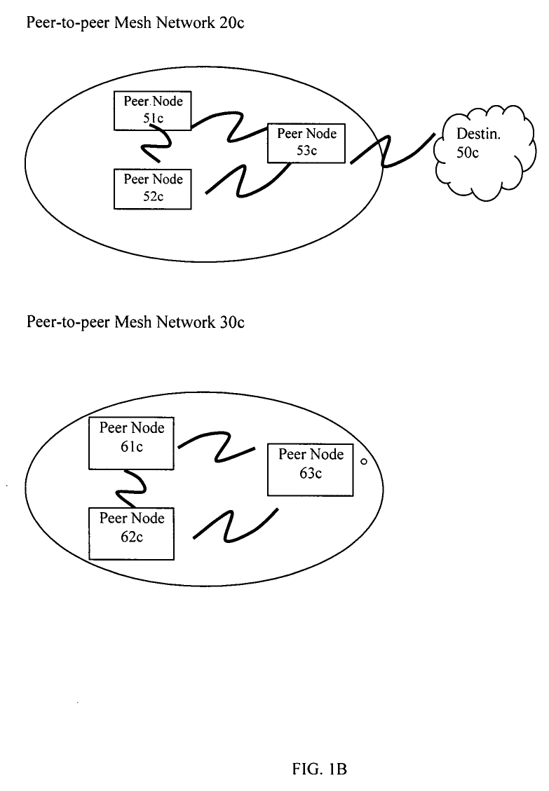

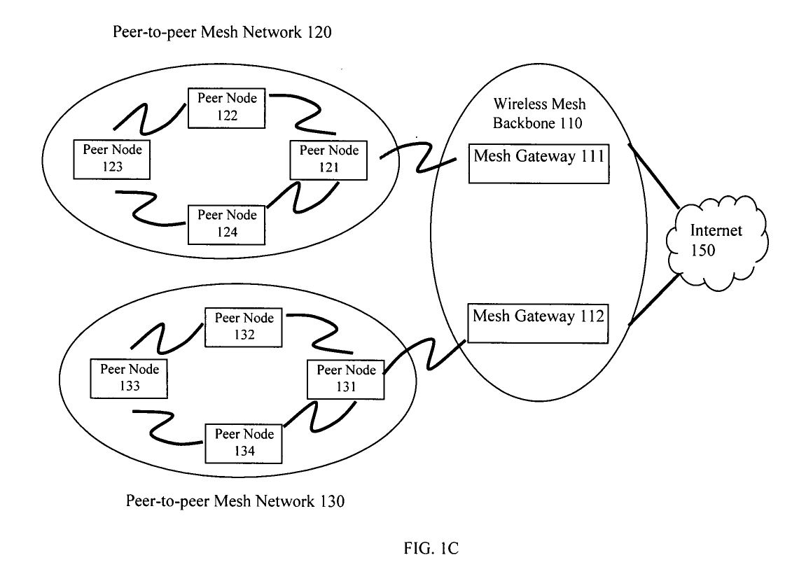

Refer to FIG. 1C, which shows a wireless mesh network 100 diagram in accordance with the present invention. As shown in FIG. 1C, a peer-to-peer network comprises a plurality of peer nodes which may be connected to the Internet through a mesh gateway in a wireless mesh backbone. For example, peer-to-peer network 120 includes peer nodes 121-124 which are connected to the Internet 150 via the mesh gateway 111 in wireless mesh backbone 110. In another example, peer-to-peer network 130 includes peer nodes 131-134 which are connected to the Internet via mesh gateway 112 in the same wireless mesh backbone 110.

In accordance with the present invention, each peer node 121-124 and 131-134 may maintain a minimum set of close neighbors in its respective neighbor list. These close neighbors may help each other identify a function that can be done by each node. For example, a neighbor of peer node 122, such as peer node 121, may be able to relay a data packet transmitted by peer node 122. In another example, a neighbor of peer node 124, such as peer node 123, may be able to hear from peer node 124. In one embodiment, a group of neighbors may be formed by a probe packet, such as a slow probe packet, such that a gradient table may be built thereon later.

In accordance with the present invention, mesh gateways 111 and 112 may be defined as bridges between a traditional network, such as an Internet 150, and a wireless mesh network, such as peer-to-peer networks 120 and 130. Once information gets on mesh gateways 111 and 112, it is available on the Internet 150. Thus, mesh gateways 111 and 112 ensure connections to the Internet 150. As can be seen from FIG. 1C, peer-to-peer network 120 may comprise a plurality of peer nodes 121-124, which may connect to mesh gateway 111, which in turn connects to the Internet 150. Peer-to-peer mesh network 130 may comprise a plurality of peer nodes 131-134, which may connect to mesh gateway 112, which in turn connects to the Internet 150. In another embodiment, where an application other than the Internet application is used, mesh gateways may be substituted with any node that ensures connections to other nodes or any destination connected to the network.

In a preferred embodiment, mesh gateway 111 may broadcast a connection signal indicator (CSI) to indicate to its peers, such as peer node 121, that it has a guaranteed connection to the Internet 150. In a preferred embodiment, the CSI may be implemented in mesh gateway 111 as an entry in a gradient table having mesh gateway 111 set as both the destination and the source. Furthermore, in the preferred embodiment, the distance to source is set to 0 hop in the gradient entry. In the preferred embodiment, mesh gateway 111 may utilize a probe packet, such as a fast probe packet, to indicate such CSI entry and thus initiate such CSI entry.

In accordance with the present invention, peer node 121 may add the CSI into its own routing tables and increase the distance to source to 1 hop as it receives the CSI from mesh gateway 111. In order to confirm its connectivity to the Internet 150, peer node 121 may try to establish a route to mesh gateway 111 based on the CSI. Additionally, peer node 121 may broadcast CSI to its own peers, such as peer nodes 122 and 124. Each of peer nodes 122 and 124 may also add the CSI into their own routing tables and increase the distance to source to 2 hops (i.e. through peer node 121 to mesh gateway 111) as they receive the CSI. Peer nodes 122 and 124 may then broadcast the CSI to for example peer node 123. Accordingly, peer node 123 may add the CSI into its own routing table and increase the distance to source to 3 hops (i.e. through peer node 122 or 124 to peer node 121 to mesh gateway 111).

In one embodiment, the same method can be repeated to each peer node in peer-to-peer mesh network 120 with n hops to mesh gateway 111. As long as all of peer nodes 121-124 within peer-to-peer mesh network 120 have the CSI in their routing table and are able to establish routing for the CSI entry (i.e. through ‘n’ number of hops), then all peer nodes 121-124 can communicate with all the other nodes within peer-to-peer mesh network 120 and get on the Internet 150.

In one preferred embodiment, the CSI entry may be identified as a routing table entry with the same source and destination address. However, if a wireless mesh node does not have a CSI entry or can not establish routing for the CSI entry, in a preferred embodiment, the node may start searching for additional peers, even at the expense of dropping existing peers, until it can receive the CSI entry from its peers and can establish routing for the CSI entry. In one embodiment, searching for additional peers may be terminated after at least one peer is found. Preferably, the search may be terminated after a predetermined number of peers are found. Alternatively, searching for additional peer may be terminated after no peer is found. Preferably, the search may be terminated after a predetermined number of failed attempts is counted. Alternatively, the search may be terminated after a predetermined period of time. In such a case, the termination may be regardless of any successful or failed attempt.

For example, peer node 123 in peer-to-peer mesh network 120 may not have a CSI entry in its routing table. Peer node 123 may send a request to the rest of the peer nodes 121, 122, and 124 for the CSI entry. Peer node 122 may send the CSI entry to the requesting peer node 123 first such that peer node 123 may update its routing table with the CSI entry received from peer node 122 with an incremented number of hop, namely 3 hops to mesh gateway 111. Peer node 123 may then try to establish routing for the CSI entry. If for any reason, the routing cannot be established, peer node 123 may send another request to the rest of peer nodes 121, 122 and 124 again for the CSI entry. In one example, peer node 123 may send a predetermined number of requests, such as 3 requests, to peer nodes 121, 122 and 124 for the CSI entry. If the peer node 123 does not receive any information from peer nodes 121, 122 and 124, or the routing cannot be established based on the information received from peer nodes 121, 122 and 124, then peer node 123 may stop sending the request. Alternatively, peer node 123 may also stop sending the request after the CSI entry information is received from for example 2 nodes, such as peer nodes 121 and 122. Alternatively, peer node 123 may stop sending the request after for example 30 seconds without receiving any response back from peer nodes 121, 122 and 124.

To avoid looping where a node continuously updates its routing table because all of its peers have CSI entries in their respective routing table, in a preferred embodiment, the CSI entry may only be received from nodes that are closer to the gateway, or a node ensuring a network connection, than the node itself. Take the example given above. If peer node 121 is 1 hop away from mesh gateway 111, peer node 122 is 2 hops away from mesh gateway, and peer node 123 is 3 hops away from mesh gateway 111, and peer node 123 has both peer node 121 and peer node 122 as its peers, then peer node 122 only receives the CSI from peer node 121 instead of peer node 123.

In a preferred embodiment, peer node 122 should never accept the CSI from the peer node 123 as long as peer node 122 has peer node 121 in its neighbor list. For example, if peer node 122 loses peer node 121 from its neighbor list, peer node 122 can then accept the CSI from peer node 123. Once peer node 122 accepts the CSI from peer node 123, peer node 122 becomes 4 hops away from mesh gateway 111, through peer node 123.

As mentioned before, the present invention may be extended to applications other than the Internet. For any network that is covered by a wireless peer-to-peer network, to avoid the cluster problem, in a preferred embodiment, one of the nodes within the network can be assigned the task of initiating a CSI-like entry for the whole network. Alternatively, a gateway-like connection, which guarantees a network connection to a destination, may take up the task of initiating a CSI-like entry for the whole network. Alternatively, each node within the network may broadcast its own signal indicating its connection to a destination connected to the network. Other nodes could then search for or request for this signal when attempting to connect to the destination, wherein the destination may be a node, a gateway or any hardware or software connected to the network.

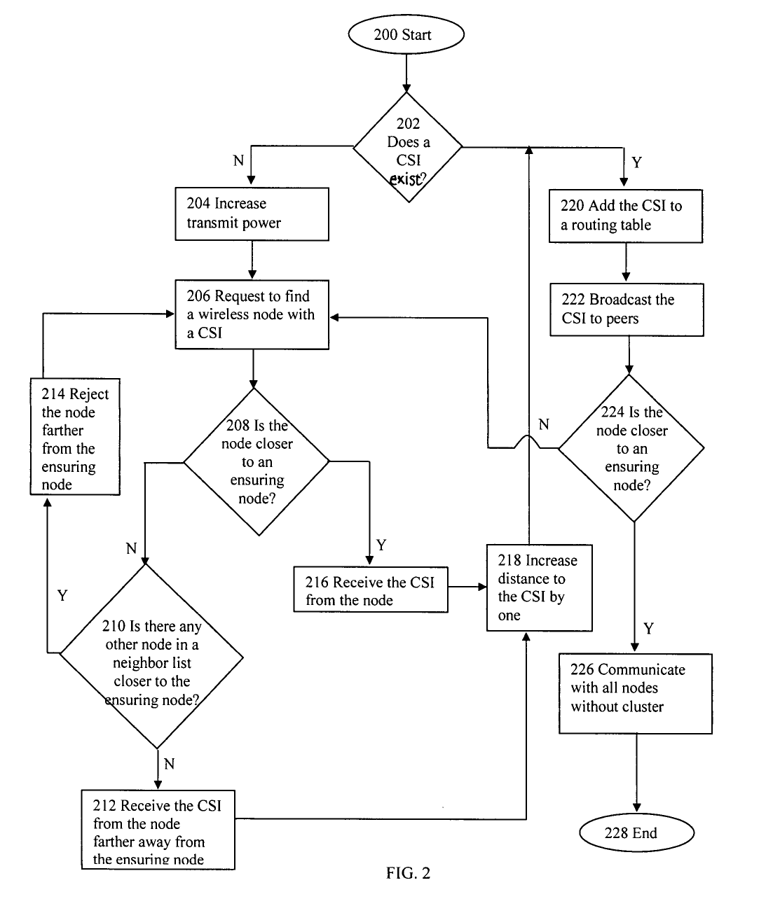

Refer now to FIG. 2, which illustrates a flow chart of a method to avoid a cluster in a wireless mesh network in accordance with the present invention. The method of the present invention may allow each node in the wireless mesh network to be aware of its connection status to the rest of the nodes within the network through a signal indicator such as a connection status indicator (CSI).

As shown in FIG. 2., the method may start at step 200. Then at step 202, a peer node, such as peer node 122, may first determine if a CSI entry exist within itself. In a preferred embodiment, the CSI may be implemented as an entry in the routing table with mesh gateway 111 as both the destination and the source.

In one embodiment, if peer node 122 does not have such CSI entry, then peer node 122 may increase its transmit power at step 204. For example, peer node 122 may increase its probe power every slow probe period and assert BIT_1 in the message field of its slow probe request packet. Alternatively, peer node 122 may increase its search distance or bandwidth to cover a broader area in order to locate CSI.

Then, at step 206, peer node 122 may request to find a mesh node with the CSI. In one embodiment, if any nearby mesh nodes hear such request, peer node 122 may be included into the nearby mesh nodes' neighbor list. Peer node 122 may also be marked as the mesh node that requires the nearby mesh nodes to relay a data packet.

When the nearby mesh nodes, such as peer nodes 121 and 123, send out their respective CSI, peer node 122 may first determine if the nearby mesh nodes are closer to mesh gateway 111 than it is at step 208. In this example, peer node 121 is one hop away from mesh gateway 111, while peer node 123 is three hops away from mesh gateway 111. As a result, peer node 122 will choose peer node 121 to receive its respective CSI at step 216.

On the other hand, since peer node 123 is not closer to mesh gateway 111 than peer node 122, peer node 122 would determine if any other node in its neighbor list, such as peer node 121, exists at step 210. If peer node 121 exists in peer node 122's peer list, than peer node 122 will not accept the CSI from peer node 123 at step 214 since peer node 121 is closer to mesh gateway 111 than peer node 123. Consequently, going to mesh gateway 111 through peer node 121 is less costly for peer node 122.

However, if peer node 121 no longer exists in peer node 122's peer list, then peer node 122 would then receive the CSI from peer node 123 at step 212. Once the CSI is received by peer node 122, peer node 122 may increase the distance to source by one step 218. For example, in case where peer node 122 receives the CSI from peer node 123, the distance to source is increased to 4 hops by peer node 122.

At step 220, the CSI is added to the routing table of peer node 122. Then, at step 222, peer node 122 may broadcast its respective CSI to its peers such that its peer may request to relay any data packet to mesh gateway 111 through peer node 122.

Once the CSI is added into the routing table, peer node 122 may determine if a routing for such CSI entry can be established at step 224. If so, then peer node 122 may communicate with all other nodes within peer-to-peer mesh network 120 without forming any cluster. The method then ends at step 228.

However, if the routing cannot be established for the CSI entry at step 224, then the method may return to step 206 where peer node 122 may request to find another mesh node with a CSI. The method may repeat from step 206 to step 224 until a routing for a CSI entry can be established for peer node 122, and thus peer node 122 may communicate with all other nodes within peer-to-peer mesh network 120 without forming any cluster. Optionally, peer node 122 may stop requesting to find another mesh node with a CSI after for example a predetermined successful or failed attempt. The method then ends at step 228.

Although the invention has been described in considerable detail with reference to the preferred version thereof, other versions are within the scope of the present invention. Therefore, the spirit and scope of the appended claims should not be limited to the description of the preferred version contained herein.

What is claimed is:

1. A method to avoid a cluster in a wireless mesh network, said method comprising:
locating a node with a direct or indirect connection to a destination connected to the network.

2. The method of claim 1, wherein said locating comprises a search or broadcast for a signal indicator, indicating said direct or indirect connection to said destination.

3. The method of claim 1, wherein said locating comprises increasing a transmit power or distance or bandwidth until said node is located.

4. The method of claim 1, further comprising directly connecting, via a wired or wireless connection, to said node, when said locating is successful.

5. The method of claim 1, wherein said locating is terminated after at least one successful or failed attempt.

6. The method of claim 1, wherein said locating is terminated after a predetermined number of successful or failed attempts.

7. The method of claim 1, wherein said locating is terminated after a predetermined period of time.

8. The method of claim 7, wherein said termination is regardless of any successful or failed attempt.

9. The method of claim 1, further comprising adding said node or an indicator of said node to a routing table, a neighbor list, or a peer list, when said locating is successful.

10. The method of claim 9, wherein said adding of said node or said indicator of said node is done when no node or no indicator of any node with said direct or indirect connection to said destination exists in said routing table, neighbor list, or peer list.

11. The method of claim 1, further comprising determining whether said locating is successful.

12. The method of claim 11, further comprising determining a distance between said node to said destination.

13. The method of claim 12, wherein said determining said distance comprises determining number of hops to said destination.

14. The method of claim 12, further comprising accepting or rejecting said node based on said determining said distance.

15. A method to avoid a cluster in a wireless mesh network, said method comprising:
broadcasting in said network when a direct or indirect connection to a destination connected to said network exists.

16. The method of claim 15, further comprising locating said broadcasting or a node with said broadcasting.

17. The method of claim 15, wherein said broadcasting comprises a signal indicator, indicating said direct or indirect connection to said destination.

18. A wireless mesh network comprising:
means for ensuring a direct or indirect connection to a destination connected to said network; and
a node indirectly connecting to said destination through or through the use of said means.

19. The network of claim 18, wherein said means is a second node.

20. The network of claim 18, wherein said means is a signal indicator.

21. The network of claim 18, wherein said ensuring comprises broadcasting said direct or indirect connection to said destination.

22. The network of claim 18, wherein said ensuring comprises locating said direct or indirect connection to said destination.

23. A wireless mesh network comprising:
a node with a direct or indirect connection to a destination connected to said network, wherein said node broadcasts in said network its direct or indirect connection to said destination.

24. The network of claim 23, further comprising a second node directly connecting to said first node, via a wired or wireless connection.

25. The network of claim 24, wherein said second node directly connects to said first node by adding said first node or an indicator of said first node to a routing table, a neighbor list, or a peer list.

26. The network of claim 23, further comprising a second node, wherein said second node locates or attempts to locate said broadcasting or said first node.

27. The method of claim 23, wherein said broadcast comprises a signal indicator, indicating said direct or indirect connection to said destination.

28. A wireless mesh network comprising:
a node, wherein said node locates or attempts to locate a direct or indirect connection to a destination connected to said network.

29. The network of claim 28, wherein said locating or attempting to locate comprises a search or broadcast for a signal indicator, indicating said direct or indirect connection to said destination.

30. The network of claim 28, wherein said locating or attempting to locate comprises increasing a transmit power or distance or bandwidth until said node is located.

31. The network of claim 28, wherein said node connects, via a wired or wireless connection, to said direct or indirect connection to said destination, when said locating is successful.

32. The network of claim 28, wherein said locating or attempting to locate is terminated after at least one successful or failed attempt.

33. The network of claim 28, wherein said locating or attempting to locate is terminated after a predetermined number of successful or failed attempts.

34. The network of claim 28, wherein said locating or attempting to locate is terminated after a predetermined period of time.

35. The network of claim 34, wherein said termination is regardless of any successful or failed attempt.

36. The network of claim 28, further comprising a second node with a direct or indirect connection to a destination connected to said network.

37. The network of claim 36, wherein said first node directly connects to said second node by adding said second node or an indicator of said second node to a routing table, a neighbor list, or a peer list.

38. The network of claim 37, wherein said adding of said second node or said indicator of said second node is done when no node or no indicator of any node with said direct or indirect connection to said destination exists in said routing table, neighbor list, or peer list.

39. The network of claim 36, wherein a distance between said second node to said destination is determined.

40. The network of claim 36, wherein said determining said distance comprises determining number of hops to said destination.

41. The network of claim 36, wherein said second node is accepted or rejected based on said determining said distance.

42. An electronic device in a wireless network, comprising:
a hardware or software capable of connecting to said network, wherein the device locates or attempts to locate an indirect connection to a destination.

43. The device of claim 42, wherein said locating or attempting to locate comprises a search or broadcast for a signal indicator, indicating a direct or indirect connection to said destination.

44. The device of claim 42, wherein said locating or attempting to locate comprises increasing a transmit power or distance or bandwidth until said indirect connection is located.

45. The device of claim 42, wherein said indirect connection comprises directly connecting, via a wired or wireless connection, to a node or a second electronic device in said network with said direct or indirect connection to said destination.

46. The device of claim 42, wherein said locating or attempting to locate is terminated after at least one successful or failed attempt.

47. The device of claim 42, wherein said locating or attempting to locate is terminated after a predetermined number of successful or failed attempts.

48. The device of claim 42, wherein said locating or attempting to locate is terminated after a predetermined period of time.

49. The device of claim 48, wherein said termination is regardless of any successful or failed attempt.

50. The device of claim 42, further comprising adding a node or a second electronic device in said network or an indicator of said node or said second device to a routing table, a neighbor list, or a peer list, when said locating is successful.

51. The device of claim 50, wherein said adding is done when the device of claim 50 has no direct or indirect connection to said destination in said routing table, neighbor list, or peer list.

52. The device of claim 42, further comprising determining whether said locating is successful.

53. The device of claim 52, further comprising determining a distance of said indirect connection to said destination.

54. The device of claim 53, wherein said determining said distance comprises determining number of hops to said destination.

55. The device of claim 53, further comprising accepting or rejecting said indirect connection based on said determining said distance.

56. An electronic device in a wireless mesh network comprising:
a hardware or software capable of connecting to said network, wherein the device directly or indirectly connects to a destination within said network and broadcasts to said network said direct or indirect connection.

57. The device of claim 56, further comprising a second electronic device in said network directly connects to said first device, via a wired or wireless connection.

58. The device of claim 57, wherein said second device directly connects to said first device by adding said first device or an indicator of said first device to a routing table, a neighbor list, or a peer list.

59. The device of claim 56, further comprising a second device, wherein said second device locates or attempts to locate said broadcasting or said first device.

60. The device of claim 56, wherein said broadcast comprises a signal indicator, indicating said direct or indirect connection to said destination.
